(19) United States
(12) Patent Application Publication
(10) Pub. No.: US 2026/0297725 A1
(43) Pub. Date: Oct. 1, 2026

(54) SPUTTERING APPARATUS AND CONTROL METHOD

(71) Applicant: Tokyo Electron Limited, Tokyo (JP)

(72) Inventors: Takahiro KAWAWA, Yamanashi (JP); Masaki SUGIURA, Tokyo (JP)

(21) Appl. No.: 19/565,921

(22) Filed: Mar. 13, 2026

(30) Foreign Application Priority Data
Mar. 25, 2025 (JP) 2025-049771

(51) Int. Cl. C23C 14/54; C23C 14/35; C23C 14/50; H10P 72/72

(52) U.S. Cl. CPC C23C 14/54; C23C 14/35; C23C 14/50; H10P 72/72

(57) ABSTRACT

A sputtering apparatus includes: a holder configured to hold a target; a power supply configured to supply electric power to the holder; a magnet provided on a rear surface of the holder; a magnet driver configured to reciprocate the magnet; and a controller, wherein the controller includes: a power controller configured to control the electric power supplied from the power supply to the holder; a magnet operation controller configured to control the magnet driver; and a power calculator configured to calculate integrated power, which is an integrated value of the electric power supplied from the power supply to the holder for each of regions divided in a direction in which the magnet reciprocates, and wherein the controller controls at least one of the electric power supplied to the holder or a reciprocation speed of the magnet to reduce bias in the integrated power for each of the regions.

### CROSS-REFERENCE TO RELATED APPLICATION

This application is based upon and claims the benefit of priority from Japanese Patent Application No. 2025-049771, filed on Mar. 25, 2025, the entire contents of which are incorporated herein by reference.

### TECHNICAL FIELD

The present disclosure relates to a sputtering apparatus and a control method.

### BACKGROUND

Patent Document 1 discloses a substrate processing apparatus including a target and a magnet mechanism that reciprocates a magnet in a horizontal direction on a rear surface of the target.

### PRIOR ART DOCUMENT

### Patent Document

Patent Document 1: Japanese Patent No. 7394676

### SUMMARY

According to one embodiment of the present disclosure, a sputtering apparatus includes: a holder configured to hold a target; a power supply configured to supply electric power to the holder; a magnet provided on a rear surface of the holder; a magnet driver configured to reciprocate the magnet; and a controller, wherein the controller includes: a power controller configured to control the electric power supplied from the power supply to the holder; a magnet operation controller configured to control the magnet driver; and a power calculator configured to calculate integrated power, which is an integrated value of the electric power supplied from the power supply to the holder for each of regions divided in a direction in which the magnet reciprocates, and wherein the controller controls at least one of the electric power supplied to the holder or a reciprocation speed of the magnet to reduce bias in the integrated power for each of the regions.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an exemplary schematic cross-sectional view of a sputtering apparatus.

FIGS. 2A and 2B are exemplary schematic diagrams showing a configuration of a driver.

FIG. 3 is an exemplary graph showing a position of a magnet, and a current, a voltage, and power supplied to a target.

FIG. 4 is an exemplary graph showing a relationship between a magnet position and integrated power.

FIG. 5 is an exemplary flowchart showing a control of a film formation process.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the drawings. In each drawing, same components are denoted by same reference numerals, and redundant explanations thereof may be omitted.

### [Sputtering Apparatus]

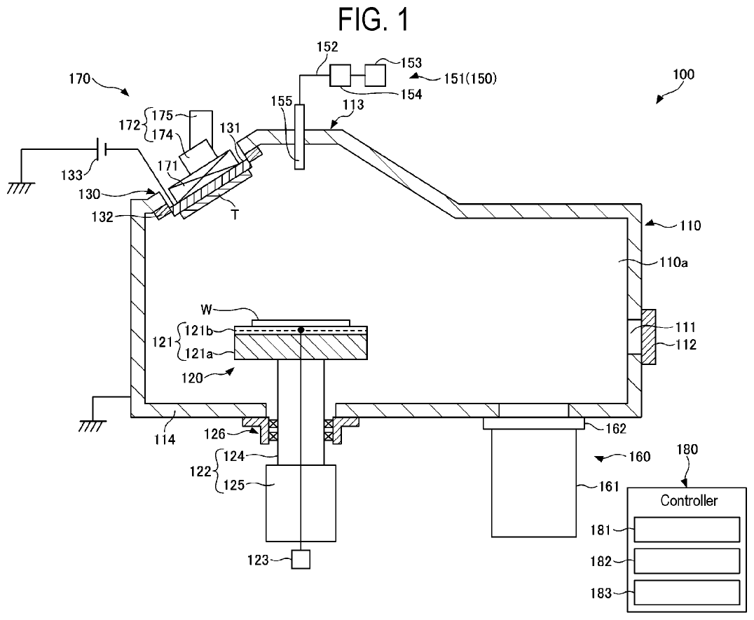

An example of a sputtering apparatus 100 will be described by using FIG. 1. FIG. 1 is an exemplary schematic cross-sectional view of the sputtering apparatus 100. The sputtering apparatus 100 is a physical vapor deposition (PVD) apparatus that deposits a substance (sputtered particles described below) onto a semiconductor wafer (hereinafter, simply referred to as a “substrate W”) which is an example of a substrate, to form a film.

The sputtering apparatus 100 includes a processing container 110 having an internal space 110a in which a film formation process is performed on the substrate W. The sputtering apparatus 100 further includes, as components for performing the film formation process on the substrate W inside the processing container 110, a stage mechanism 120, a target holder 130, a gas supply 150, a gas discharger 160, and a magnet mechanism 170. The sputtering apparatus 100 further includes a controller 180 that controls an operation of each component.

The processing container 110 is made of, for example, aluminum. The processing container 110 is connected to a ground potential. That is, the processing container 110 is grounded. The processing container 110 includes a loading/unloading port 111 that brings the internal space 110a into communication with an outside of the processing container 110, and a gate valve 112 that opens and closes the loading/unloading port 111. When the gate valve 112 is open, the sputtering apparatus 100 loads and unloads the substrate W via the loading/unloading port 111 by using a transfer device (not shown). The processing container 110 further includes a tapered portion 113 having an approximately tapered shape (e.g., an approximately quadrangular pyramid shape, a circular conical shape, or the like) on a ceiling portion located above the stage mechanism 120.

The stage mechanism 120 includes a stage 121 disposed inside the processing container 110 and a support driver 122 that operably supports the stage 121. The stage 121 includes a substantially disk-shaped base 121a and an electrostatic chuck 121b fixed on the base 121a.

The base 121a is made of, for example, aluminum. The base 121a is fixed to an upper end of the support driver 122. The support driver 122 moves the base 121a such that the electrostatic chuck 121b is disposed at a predetermined height position in the internal space 110a. The stage mechanism 120 may further include a temperature controller (not shown) that adjusts a temperature of the base 121a to control a temperature of the substrate W placed on the stage 121.

The electrostatic chuck 121b includes a dielectric film and an electrode (both not shown) provided on an inner layer of the dielectric film. The electrode of the electrostatic chuck 121b is connected to a DC power supply 123. The electrostatic chuck 121b electrostatically attracts the substrate W placed on an upper surface of the electrostatic chuck 121b by generating an electrostatic force in the dielectric film by a DC voltage supplied to the electrode from the DC power supply 123.

The support driver 122 includes a columnar support shaft 124 that holds the base 121a, and an operating device 125 that operates the support shaft 124. The support shaft 124 extends along a vertical direction from the internal space 110a of the processing container 110 via a bottom portion 114 to the outside of the processing container 110.

The operating device 125 is provided outside the processing container 110. The operating device 125 holds a lower end of the support shaft 124. The operating device 125 rotates the support shaft 124 under a control of the controller 180. The operating device 125 also moves the support shaft 124 up and down in the vertical direction. The stage 121 rotates and moves up and down inside the processing container 110 by an operation of the operating device 125.

The stage mechanism 120 further includes a sealing structure 126 disposed between the bottom portion 114 of the processing container 110 and the support shaft 124 to seal a gap while allowing the support shaft 124 to operate. As the sealing structure 126, for example, a magnetic fluid seal is used.

The target holder 130 holds a target (sputtering target) T, which is a cathode target, at a position spaced apart upward from the stage 121. In addition, the sputtering apparatus 100 includes one or more (one in the example of FIG. 1) target holders 130.

The target holder 130 includes a metal holder 131 that holds a target T, and an insulating member 132 that supports the holder 131 by fixing an outer peripheral portion of the holder 131.

The target T held by the holder 131 is made of a material containing a film-forming substance. The target T is a rectangular flat plate. Further, in FIG. 1, the target T is formed in a rectangular shape with a direction perpendicular to a paper surface as its longitudinal direction.

The holder 131 is formed in a rectangular shape that is slightly larger than the target T in a plan view. The holder 131 is fixed to an inclined surface of the tapered portion 113 via the insulating member 132. Since the holder 131 is fixed to the inclined surface of the tapered portion 113, the holder 131 holds a front surface of the target T (a sputtering surface exposed to the internal space 110a) in an inclined state with respect to a normal direction of the substrate W placed on the stage 121 (a direction of a rotation axis of the stage 121). In other words, the front surface of the target T is the sputtering surface exposed to the internal space 110a. A rear surface, which is a surface opposite the front surface of the target T, is a held surface to be held by the holder 131. A front surface of the holder 131 (a surface facing the internal space 110a) is a holding surface that holds the target T. A rear surface, which is a surface opposite the front surface of the holder 131, is a surface facing the outside of the processing container 110.

Further, the target holder 130 electrically connects a power supply 133 to the target T held by the holder 131. The power supply 133 applies a negative DC voltage to the target T via the holder 131.

The gas supply 150 includes an excitation gas supply 151 that is provided in the tapered portion 113 to supply an excitation gas.

The excitation gas supply 151 includes a pipe 152 that circulates a gas outside the processing container 110. The excitation gas supply 151 further includes a gas source 153, a flow rate controller 154, and a gas introducer 155, which are arranged in order from an upstream side to a downstream side of the pipe 152.

The gas source 153 stores an excitation gas (e.g., argon gas) and supplies the gas to the pipe 152. The flow rate controller 154 applies, for example, a mass flow controller, to adjust a flow rate of the gas supplied into the processing container 110. The gas introducer 155 introduces the gas from the outside to the inside of the processing container 110.

The gas discharger 160 includes a depressurization pump 161 and an adapter 162 for fixing the depressurization pump 161 to the bottom portion 114 of the processing container 110. The gas discharger 160 depressurizes the internal space 110a of the processing container 110 under a control of the controller 180.

The magnet mechanism 170 applies a magnetic field to the target T. By applying the magnetic field to the target T, the magnet mechanism 170 induces plasma in the target T. The magnet mechanism 170 includes a driver 171 and a magnet driver 172 that operably holds the driver 171.

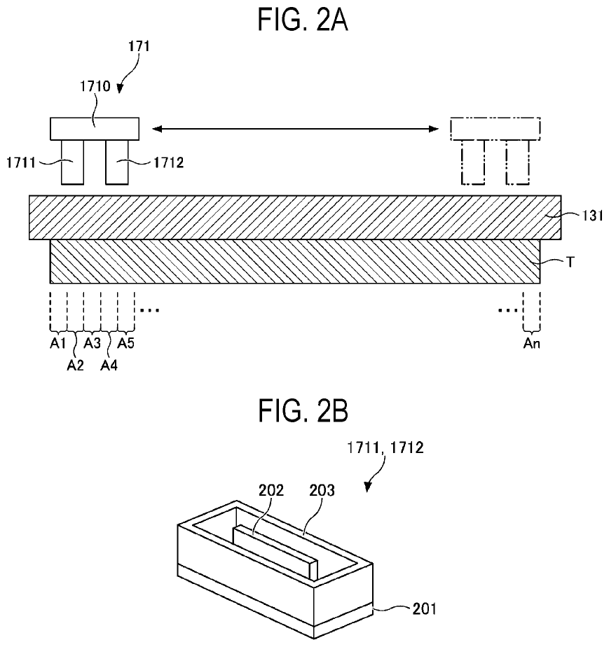

FIGS. 2A and 2B are exemplary schematic diagrams showing a configuration of the driver 171. FIG. 2A is an exemplary cross-sectional view showing the configuration of the driver 171. Further, in FIG. 2A, the target T is formed in a rectangular shape with its longitudinal direction extending in a left-right direction of a paper surface.

The driver 171 includes a support body 1710 and magnet units 1711 and 1712. The support body 1710 supports the magnet units 1711 and 1712. The driver 171 having the magnet units 1711 and 1712 is arranged on the rear surface of the holder 131 (the rear surface of the target T).

The magnet units 1711 and 1712 have substantially rectangular shapes in a plan view. When held by the magnet driver 172, long sides of the magnet units 1711 and 1712 extend parallel to a transverse direction of the rectangular target T (a direction perpendicular to the paper surface in FIG. 2A), while short sides of the magnet units 1711 and 1712 extend parallel to a longitudinal direction of the rectangular target T (the left-right direction of the paper surface in FIG. 2A). The magnet units 1711 and 1712 are arranged spaced apart in the longitudinal direction of the target T (the left-right direction of the paper surface in FIG. 2A).

FIG. 2B is an exemplary perspective view of the magnet units 1711 and 1712. Since the magnet units 1711 and 1712 have a same configuration, the magnet unit 1711 will be described as an example. Further, FIG. 2B is a perspective view of the magnet unit 1711 as seen from the rear surface of the holder 131.

The magnet unit 1711 includes a yoke 201, a magnet 202, and a magnet 203.

The yoke 201 is formed in a rectangular flat plate shape in a plan view. A longitudinal direction of the yoke 201 is a longitudinal direction of the magnet unit 1711. A transverse direction of the yoke 201 is a transverse direction of the magnet unit 1711 and is a direction in which the driver 171 reciprocates (the left-right direction of the paper surface in FIG. 2A).

The magnet 202 is formed in a rectangular parallelepiped shape and is arranged along the longitudinal direction at a center of the yoke 201. The magnet 203 is formed in a rectangular ring shape and is provided so as to surround four sides of the magnet 202. The magnets 202 and 203 are magnetized in opposite directions to each other in a direction perpendicular to a surface of the yoke 201 facing the magnet 202.

Permanent magnets may be used as the magnets 202 and 203. There are no particular limitations on a material that constitutes the magnets 202 and 203 as long as the material has an appropriate magnetic force. Examples of the material include iron, cobalt, nickel, samarium, and neodymium.

In addition, although the magnets 202 and 203 have been described as being magnetized in the opposite directions to each other, the present disclosure is not limited thereto. The magnets 202 and 203 may have same polarity. Further, although the magnet unit 1711 which has two magnets has been described as an example, the present disclosure is not limited thereto. The magnet unit 1711 may be configured as having one magnet or three or more magnets.

Returning to FIG. 1, the magnet driver 172 includes a reciprocating mechanism 174 and an attacher/detacher 175.

The reciprocating mechanism 174 reciprocates the driver 171 having the magnet units 1711 and 1712 along the longitudinal direction of the target T (the direction perpendicular to the paper surface in FIG. 1 and the left-right direction of the paper surface in FIG. 2A). In addition, in FIG. 2A, a direction in which the driver 171 reciprocates is indicated by an arrow.

The attacher/detacher 175 moves the driver 171 having the magnet units 1711 and 1712 toward and away from the target T (the holder 131).

The controller 180 controls an operation of each component of the sputtering apparatus 100.

The controller 180 opens the gate valve 112 and controls the transfer device (not shown) to transfer the substrate W from the loading/unloading port 111 into the processing container 110 and place the substrate W on the stage 121. After the transfer device retreats from the loading/unloading port 111, the controller 180 closes the gate valve 112. The controller 180 also controls the DC power supply 123 to hold the substrate W on the electrostatic chuck 121b. The controller 180 also controls the operating device 125 to rotate the stage 121.

The controller 180 also controls the flow rate controller 154 to introduce an excitation gas (argon gas) into the internal space 110a, and controls the gas discharger 160 to control a pressure in the internal space 110a.

The controller 180 also controls the power supply 133 to apply a negative DC voltage to the target T via the holder 131. Thus, magnetron plasma is generated in a vicinity of the target T, and the sputtering surface of the target T is sputtered by a magnetron sputter. In addition, the driver 171 includes two magnet units 1711 and 1712. Therefore, the sputtering surface of the target T is magnetron-sputtered at a position (region) corresponding to the magnet unit 1711, and the sputtering surface of the target T is magnetron-sputtered at a position (region) corresponding to the magnet unit 1712.

Sputtered particles emitted from the sputtering surface of the target T are deposited on a surface of the substrate W. As described above, the substrate W is subjected to the film formation process.

The controller 180 also controls the magnet driver 172 (reciprocating mechanism 174) to reciprocate the driver 171 having the magnet units 1711 and 1712 in the longitudinal direction of the target T. Therefore, a position at which the sputtered particles are emitted from the sputtering surface of the target T, that is, a position at which the sputtering surface of the target T is consumed (eroded), is controlled.

As shown in FIG. 1, the controller 180 also includes a power controller 181, a magnet operation controller 182, and an integrated power calculator 183.

The power controller 181 controls the power supply 133 to control electric power supplied to the target T (the holder 131). In other words, the power controller 181 controls an amount of sputtering on the sputtering surface of the target T. In other words, the power controller 181 controls an amount of consumption of the target T at the position (region) from which the sputtered particles of the target T are emitted.

The magnet operation controller 182 controls the magnet driver 172 (the reciprocating mechanism 174) to control a reciprocating movement of the magnet units 1711 and 1712. In other words, the magnet operation controller 182 controls a position of a magnetic field applied by the magnet units 1711 and 1712. That is, the magnet operation controller 182 controls the position (region) from which the sputtered particles of the target T are emitted.

The integrated power calculator 183 calculates an integrated power for each of regions A1, A2, A3, . . . , An (where n is an integer) of the target T. Here, as shown in FIG. 2A, the target T is divided into the regions A1, A2, A3, . . . , An in the direction of reciprocation (indicated by the arrow in FIG. 2A) of the magnet units 1711 and 1712. Here, the integrated power calculator 183 calculates the integrated power for each of the regions A1, A2, A3, . . . , An (where n is an integer). Here, the integrated power for the region A1 is calculated by integrating time during which magnetic fields of the magnet units 1711 and 1712 are applied to the region A1 and power supplied to the target T from the power supply 133 at that time.

In addition, in the example of the sputtering apparatus 100 shown in FIG. 1, the holder 131 for holding the target T is provided on the tapered portion 113, and the sputtered particles are obliquely incident on the substrate W. However, the present disclosure is not limited thereto. A sputtering apparatus may also be used in which a holder for holding the target T horizontally (parallel to the substrate W) is provided on a ceiling surface of a processing container, and sputtered particles are incident on the substrate W approximately perpendicularly.

### [Integrated Power]

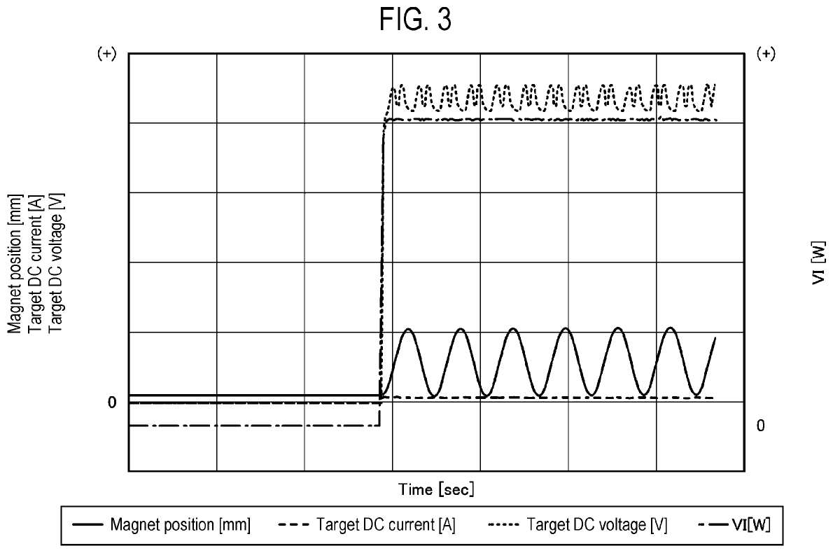

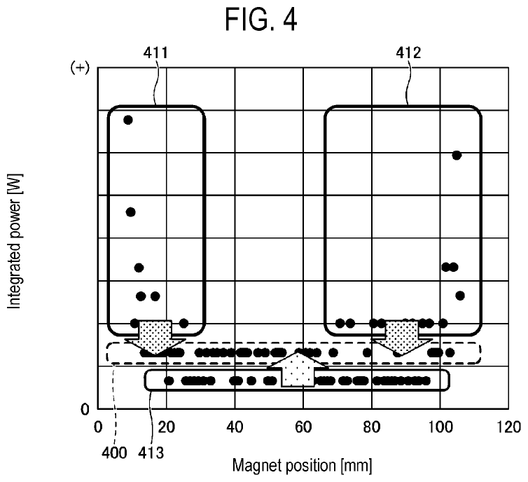

Next, the integrated power calculated for each of the regions A1, A2, A3, . . . , An (where n is an integer) of the target T will be described by using FIGS. 3 and 4.

FIG. 3 is an exemplary graph showing a position of the magnet, and a current, a voltage, and power supplied to the target T. The horizontal axis represents time. A vertical axis on the left side represents a position of the support body 1710 of the magnet units 1711 and 1712 (indicated by a solid line in FIG. 3), a DC current supplied to the target T (indicated by a dashed line in FIG. 3), and a DC voltage supplied to the target T (indicated by a dotted line in FIG. 3). A vertical axis on the right side represents electric power VI supplied to the target T (indicated by a one-dot chain line in FIG. 3).

Here, when the film formation process initiates, the magnet operation controller 182 of the controller 180 controls the magnet driver 172 (reciprocating mechanism 174) to reciprocate the magnet units 1711 and 1712. In addition, the power controller 181 of the controller 180 controls the power supply 133 so that the electric power VI supplied to the target T is constant.

The integrated power calculator 183 calculates the integrated power corresponding to each magnet position based on the magnet position and the electric power VI shown in FIG. 3.

FIG. 4 is an exemplary graph showing a relationship between the magnet position and the integrated power. The horizontal axis represents the magnet position. In other words, the horizontal axis represents a position of the target T in a longitudinal direction. The vertical axis represents the integrated power. That is, each point in the graph represents the integrated power in each of the regions A1, A2, A3, . . . , An.

Points within a range 400 (a region in the longitudinal direction of the target T) are points where the integrated power falls within a range of a predetermined target value.

On the other hand, points within ranges 411 and 412 (regions in the longitudinal direction of the target T) are points where the integrated power is greater than the range of the predetermined target value.

Points within a range 413 (a region in the longitudinal direction of the target T) are points where the integrated power is smaller than the range of the predetermined target value.

As described above, the integrated power varies for each of the regions A1 to An in the longitudinal direction of the target T, so that the consumption of the target T progresses at the point where the integrated power is large, and the consumption of the target T is suppressed at the point where the integrated power is small. Therefore, there is a concern that uniformity of the sputtering surface of the target T is decreased.

In this regard, the controller 180 calculates the integrated power for each of the regions A1 to An in the longitudinal direction of the target T during a process (during the film formation process), and controls at least one of the power supply 133 or the magnet driver 172 so as to suppress bias in the calculated integrated power. Therefore, it is possible to suppress bias in the amount of consumption of the target T and improve uniformity of the amount of consumption of the target T.

For example, the controller 180 calculates the integrated power for each of the regions A1 to An in the longitudinal direction of the target T during the process (during the film formation process), and controls at least one of the power supply 133 or the magnet driver 172 so that the integrated power falls within a predetermined target value range (the range 400).

For example, the integrated power calculator 183 of the controller 180 calculates the integrated power for each of the regions A1 to An in the longitudinal direction of the target T during the process (during the film formation process). Subsequently, the controller 180 calculates an average value of the integrated powers for the regions A1 to An. Thereafter, the controller 180 calculates a difference (a deviation) between the integrated power for each of the regions A1 to An and the average value of the integrated powers. Then, the controller 180 controls at least one of the power supply 133 or the magnet driver 172 so as to reduce the deviation.

Further, the controller 180 may control at least one of the power supply 133 or the magnet driver 172 so that a maximum absolute value of the deviation is small. In addition, the controller 180 may control at least one of the power supply 133 or the magnet driver 172 so that the maximum absolute value of the deviation is equal to or smaller than a predetermined threshold value.

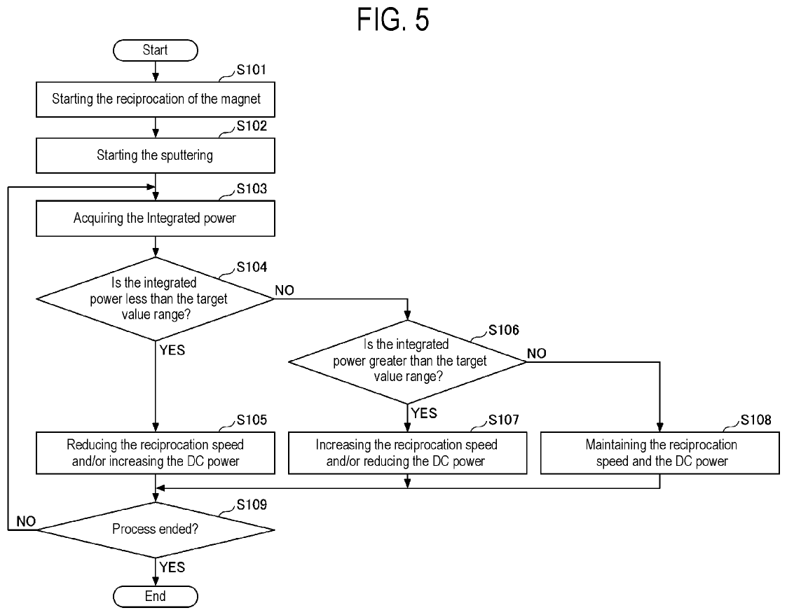

Next, an example of a control for improving the uniformity of the amount of the consumption of the target T will be described with reference to FIG. 5. FIG. 5 is an exemplary flowchart showing a control of the film formation process.

In step S101, a reciprocation of the magnet is initiated. Here, the magnet operation controller 182 of the controller 180 controls the magnet driver 172 to initiate the reciprocating of the driver 171 having the magnet units 1711 and 1712.

In step S102, a sputtering is initiated. Here, the power controller 181 of the controller 180 controls the power supply 133 to apply a negative DC voltage to the holder 131 (the target T).

In step S103, the integrated power is acquired. Here, the integrated power calculator 183 of the controller 180 calculates the integrated power for each of the regions A1 to An based on the electric power supplied to the holder 131 (the target T) and the position of the magnet (the magnet units 1711 and 1712).

In addition, as shown in FIG. 2A, the driver 171 includes two magnet units 1711 and 1712. The controller 180 calculates the integrated power for each of the regions A1 to An, assuming that the electric power supplied to the holder 131 (the target T) is supplied to the region corresponding to the range magnetron-sputtered by the magnetic fields of the magnet units 1711 and 1712.

The following process from step S104 to step S108 is performed for each region Ai (where i is any one of 1 to n).

In step S104, it is determined whether the integrated power in the region Ai is less than the range 400 of the target value.

For example, the controller 180 calculates the average value of the integrated powers for the regions A1 to An. The controller 180 also determines the range 400 of the target value that includes the calculated average value of the integrated powers. Subsequently, the controller 180 determines whether an integrated power for the region Ai is less than the range 400 of the target value.

When the integrated power in the region Ai is less than the range 400 of the target value (YES in S104), the controller 180 proceeds to step S105. When the integrated power in the region Ai is not less than the range 400 of the target value (NO in S104), the controller 180 proceeds to step S106.

In step S105, the controller 180 slows down a reciprocation speed of the magnet in the region Ai and/or increases the electric power supplied to the holder 131 (the target T) when the magnet is arranged in the region Ai.

By slowing down the reciprocation speed of the magnet in the region Ai, time for a magnetron sputtering in the region Ai is prolonged. In addition, by increasing the electric power supplied to the holder 131 (the target T) when the magnet is arranged in the region Ai, a sputtering rate is increased.

Therefore, the integrated power in the region Ai increases. For example, in the example of FIG. 4, in the region Ai included in the range 413, by increasing the integrated power, the integrated power falls within the range 400 of the target value. Then, the process of the controller 180 proceeds to step S109.

In step S106, it is determined whether the integrated power in the region Ai is greater than the range 400 of the target value.

For example, the controller 180 calculates the average value of the integrated powers for the regions A1 to An. The controller 180 also determines the range 400 of the target value that includes the calculated average value of the integrated powers. Subsequently, the controller 180 determines whether the integrated power for the region Ai is greater than the range 400 of the target value.

When the integrated power in the region Ai is greater than the range 400 of the target value (YES in S106), the controller 180 proceeds to step S107. When the integrated power in the region Ai is not greater than the range 400 of the target value (NO in S106), the controller 180 proceeds to step S108.

In step S107, the controller 180 increases the reciprocation speed of the magnet in the region Ai and/or reduces the electric power supplied to the holder 131 (the target T) when the magnet is arranged in the region Ai.

By increasing the reciprocation speed of the magnet in the region Ai, time for the magnetron sputtering in the region Ai is shortened. In addition, by reducing the electric power supplied to the holder 131 (the target T) when the magnet is arranged in the region Ai, the sputtering rate is reduced.

Therefore, the integrated power in the region Ai is reduced. For example, in the example of FIG. 4, in the region Ai included in the ranges 411 and 412, by reducing the integrated power, the integrated power falls within the range 400 of the target value. Then, the controller 180 proceeds to step S109.

In step S108, the controller 180 increases the reciprocation speed of the magnet in the region Ai and maintains the electric power supplied to the holder 131 (the target T) when the magnet is arranged in the region Ai. For example, in the example of FIG. 4, in the region Ai included in the range 400, the integrated power is maintained within the range 400 of the target value. Then, the controller 180 proceeds to step S109.

In step S109, the controller 180 determines whether or not to terminate the process. When the process is not to be terminated (NO in S109), the controller 180 returns to step S103 and repeats the processes from step S103 to step S108. When the process is to be terminated (YES in S109), the film formation process is terminated.

As described above, according to the process shown in FIG. 5, the integrated power can be made uniform in the regions A1, A2, A3, . . . , An. Therefore, it is possible to improve the uniformity of the amount of consumption on the sputtering surface of the target T.

Further, at an initiation of a next sputtering process (S102), the power supply 133 may initiate supplying electric power to the holder 131 at a timing at which a reciprocation magnet is arranged in one of the regions A1 to An where the integrated power is small. Thus, the integrated power can be made uniform in the regions A1 to An, so that it is possible to improve the uniformity of the consumption rate of the sputtering surface of the target T.

The sputtering apparatus 100 has been described above. However, the present disclosure is not limited to the above-described embodiments. Various modifications and improvements may be made within the scope of the gist of the present disclosure as recited in the claims.

According to an embodiment of the present disclosure, it is possible to provide a sputtering apparatus and a control method for improving uniformity of an amount of consumption of a sputtering target.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A sputtering apparatus, comprising:
a holder configured to hold a target;
a power supply configured to supply electric power to the holder;
a magnet provided on a rear surface of the holder;
a magnet driver configured to reciprocate the magnet; and
a controller,
wherein the controller includes:
a power controller configured to control the electric power supplied from the power supply to the holder;
a magnet operation controller configured to control the magnet driver; and
a power calculator configured to calculate integrated power, which is an integrated value of the electric power supplied from the power supply to the holder for each of regions divided in a direction in which the magnet reciprocates, and
wherein the controller controls at least one of the electric power supplied to the holder or a reciprocation speed of the magnet to reduce bias in the integrated power for each of the regions.

2. The sputtering apparatus of claim 1, wherein the controller controls at least one of the electric power supplied to the holder or the reciprocation speed of the magnet to reduce a deviation of the integrated power for each of the regions.

3. The sputtering apparatus of claim 2, wherein the controller is configured to:
calculate an average value of the integrated powers for the respective regions;
determine a range of a target value including the average value; and
perform at least one of increasing the electric power supplied to the holder or reducing the reciprocation speed of the magnet in a region where the integrated power is less than the range of the target value.

4. The sputtering apparatus of claim 2, wherein the controller is configured to:
calculate an average value of the integrated powers for the respective regions;
determine a range of a target value including the average value; and
perform at least one of reducing the electric power supplied to the holder or increasing the reciprocation speed of the magnet in a region where the integrated power is greater than the range of the target value.

5. A control method for a sputtering apparatus that includes a holder configured to hold a target, a power supply configured to supply electric power to the holder, a magnet provided on a rear surface of the holder, and a magnet driver configured to reciprocate the magnet, the control method comprising:
calculating integrated power, which is an integrated value of the electric power supplied from the power supply to the holder for each of regions divided in a direction in which the magnet reciprocates; and
controlling at least one of the electric power supplied to the holder or a reciprocation speed of the magnet to reduce bias in the integrated power for each of the regions.

6. The control method of claim 5, wherein at least one of the electric power supplied to the holder or the reciprocation speed of the magnet is controlled to reduce a deviation of the integrated power for each of the regions.

7. The control method of claim 6, wherein an average value of the integrated powers for the respective regions is calculated,
wherein a range of a target value including the average value is determined, and
wherein at least one of increasing the electric power supplied to the holder or reducing the reciprocation speed of the magnet is performed in a region where the integrated power is less than the range of the target value.

8. The control method of claim 6, wherein an average value of the integrated powers for the respective regions is calculated,
wherein a range of a target value including the average value is determined, and
wherein at least one of reducing the electric power supplied to the holder or increasing the reciprocation speed of the magnet is performed in a region where the integrated power is greater than the range of the target value.
